(19) United States
(12) Patent Application Publication
(10) Pub. No.: US 2023/0200022 A1
(43) Pub. Date: Jun. 22, 2023

(54) TWO-PHASE IMMERSION TYPE HEAT DISSIPATION SUBSTRATE

(71) Applicant: AMULAIRE THERMAL TECHNOLOGY, INC., New Taipei City (TW)

(72) Inventors: CHENG-SHU PENG, New Taipei City (TW); CHIH-HUNG SHIH, Hsinchu County (TW)

(21) Appl. No.: 17/556,946

(22) Filed: Dec. 20, 2021

(51) Int. Cl. H05K 7/20

(52) U.S. Cl. CPC H05K 7/20518; H05K 7/203; H05K 7/208

(57) ABSTRACT

A two-phase immersion type heat dissipation substrate is in contact with a heat generating element, and includes an immersion type heat dissipation base and at least one first and at least one second fin assembly that are formed on an upper surface thereof. The at least one first fin assembly is located directly above at least one high-temperature heat source area of the heat generating element, and the at least one second fin assembly is located directly above an area that is not the at least one high-temperature heat source area of the heat generating element. The at least one first and at least one second fin assembly include multiple first fins and multiple second fins, respectively. An arrangement density of the first fins is greater than that of the second fins, and a fin height of the first fins is greater than that of the second fins.

### FIELD OF THE DISCLOSURE

The present disclosure relates to a heat dissipation substrate, and more particularly to a two-phase immersion type heat dissipation substrate.

### BACKGROUND OF THE DISCLOSURE

In an immersion cooling technology, heat generating elements (such as servers and disk arrays) are directly immersed into a coolant that is non-conductive, and heat generated from operation of the heat generating elements is removed through an endothermic gasification process of the coolant. Therefore, how heat can be more effectively dissipated through the immersion cooling technology has long been an issue yet to be addressed in the relevant industry.

### SUMMARY OF THE DISCLOSURE

In response to the above-referenced technical inadequacy, the present disclosure provides a two-phase immersion type heat dissipation substrate.

In one aspect, the present disclosure provides a two-phase immersion type heat dissipation substrate configured to be in contact with a heat generating element. The two-phase immersion type heat dissipation substrate includes an immersion type heat dissipation base, at least one first fin assembly, and at least one second fin assembly. The immersion type heat dissipation base has an upper surface and a lower surface, the lower surface is configured to be in contact with the heat generating element, and the at least one first fin assembly and the at least one second fin assembly are formed on the upper surface. The at least one first fin assembly is located directly above at least one high-temperature heat source area of the heat generating element, and the at least one second fin assembly is located directly above an area that is not the at least one high-temperature heat source area of the heat generating element. The at least one first fin assembly includes a plurality of first fins, the at least one second fin assembly includes a plurality of second fins, an arrangement density of the plurality of first fins is greater than an arrangement density of the plurality of second fins, and a fin height of the plurality of first fins is greater than a fin height of the plurality of second fins.

In certain embodiments, the immersion type heat dissipation base is made from one of aluminum, copper, aluminum alloy, and copper alloy.

In certain embodiments, the immersion type heat dissipation base is immersed in a two-phase coolant, and is configured as a porous metal heat sink having a porosity greater than 5%.

In certain embodiments, a porosity of the at least one first fin assembly and a porosity of the at least one second fin assembly are both higher than a porosity of the immersion type heat dissipation base.

In certain embodiments, a fin quantity of the at least one first fin assembly is greater than a fin quantity of the at least one second fin assembly.

In certain embodiments, the at least one first fin assembly and the at least one second fin assembly are integrally formed on the upper surface of the immersion type heat dissipation base.

In certain embodiments, the at least one first fin assembly and the at least one second fin assembly are arranged successively.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a two-phase immersion type heat dissipation substrate according to a first embodiment of the present disclosure; and

FIG. 2 is a schematic side view of a two-phase immersion type heat dissipation substrate according to a second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

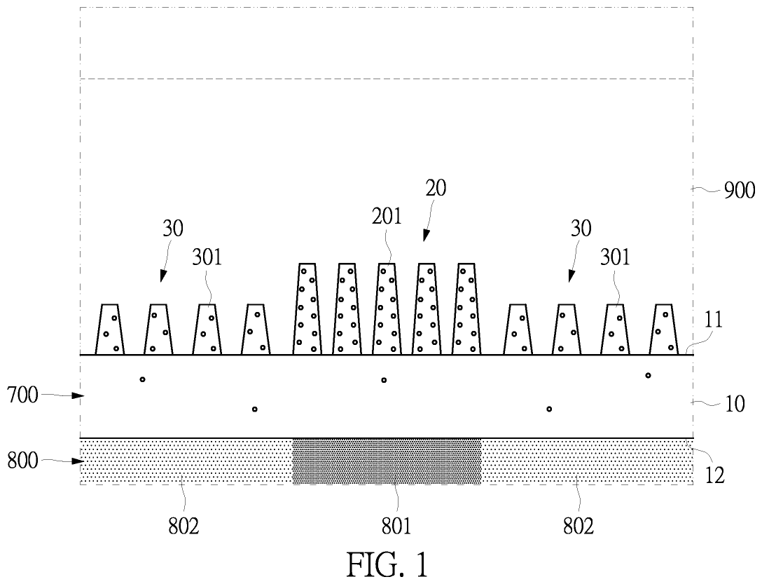

Reference is made to FIG. 1, in which one embodiment of the present disclosure is shown. The embodiment of the present disclosure provides a two-phase immersion type heat dissipation substrate 700, which is configured to be in contact with a heat generating element 800. As shown in FIG. 1, the two-phase immersion type heat dissipation substrate 700 provided in the embodiment of the present disclosure includes an immersion type heat dissipation base 10, at least one first fin assembly 20, and at least one second fin assembly 30.

In the present embodiment, the immersion type heat dissipation base 10 can be made from a high thermal conductive material, such as aluminum, copper or alloys thereof. Specifically, the immersion type heat dissipation base 10 of the present embodiment is immersed in a two-phase coolant 900, and is configured as a porous metal heat sink having a porosity greater than 5%, so as to increase an amount of bubbles that is generated and enhance an immersion type heat dissipation effect. Further, a porosity of the immersion type heat dissipation base 10 of the present embodiment is designed to be more than or equal to 5% and less than or equal to 50%.

In the present embodiment, the immersion type heat dissipation base 10 has an upper surface 11 and a lower surface 12 that are opposite to each other. The lower surface 12 of the immersion type heat dissipation base 10 is configured to be in contact with the heat generating element 800. In addition, one first fin assembly 20 and two second fin assemblies 30 are formed on the upper surface 11 of the immersion type heat dissipation base 10.

Specifically, the first fin assembly 20 of the present embodiment is located directly above a predetermined high-temperature heat source area 801 of the heat generating element 800, and the two second fin assemblies 30 are located directly above non-high-temperature heat source areas of the heat generating element 800. In the present embodiment, the high-temperature heat source area 801 is located at a center portion of the heat generating element 800. The non-high-temperature heat source areas (that is, two low-temperature heat source areas 802 that have a relatively lower heat generation temperature) are located at two sides of the center portion of the heat generating element 800. Accordingly, in the present embodiment, the first fin assembly 20 corresponds in position to the center portion of the heat generating element 800, and the two second fin assemblies 30 correspond in position to the two sides of the center portion of the heat generating element 800. Further, the first fin assembly 20 and the two second fin assemblies 30 are arranged successively. That is, the two second fin assemblies 30 are arranged successively from the first fin assembly 20 toward the outer sides.

More specifically, in the present embodiment, the first fin assembly 20 includes a plurality of first fins 201, and each of the second fin assemblies 30 includes a plurality of second fins 301. In addition, an arrangement density of the first fins 201 of the first fin assembly 20 is greater than an arrangement density of the second fins 301 of the second fin assembly 30, and a fin height of the first fins 201 of the first fin assembly 20 is greater than a fin height of the second fins 301 of the second fin assembly 30.

Therefore, in the present embodiment, the first fin assembly 20 formed on a surface of the immersion type heat dissipation base 10 is located directly above the predetermined high-temperature heat source area 801 of the heat generating element 800. In addition, the first fins 201 of the first fin assembly 20 are arranged more densely, and the fin height of the first fins 201 of the first fin assembly 20 is greater. In this way, an immersion type heat dissipation area can be increased on a limited surface area, so that high energy generated from the high-temperature heat source area 801 can be carried away and the immersion type heat dissipation effect can be further enhanced.

### Second Embodiment

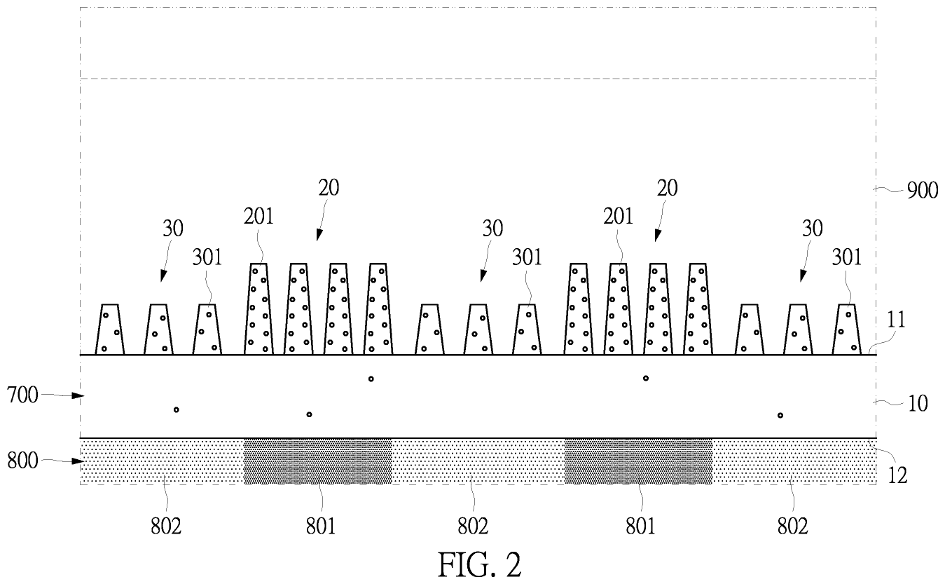

Reference is made to FIG. 2, in which a second embodiment of the present disclosure is shown. The present embodiment is substantially the same as the first embodiment, and differences there-between are illustrated below.

In the present embodiment, an immersion type heat dissipation base 10 has an upper surface 11 and a lower surface 12 that are opposite to each other. The lower surface 12 of the immersion type heat dissipation base 10 is configured to be in contact with a heat generating element 800. In addition, two first fin assemblies 20 and three second fin assemblies 30 are formed on the upper surface 11 of the immersion type heat dissipation base 10.

Specifically, the two first fin assemblies 20 of the present embodiment are located directly above two predetermined high-temperature heat source areas 801 of the heat generating element 800. In addition, the three second fin assemblies 30 are located directly above non-high-temperature heat source areas of the heat generating element 800. In the present embodiment, the two high-temperature heat source areas 801 are located at two sides of a center portion of the heat generating 800. The non-high-temperature heat source areas (that is, three low-temperature heat source areas 802 that have a relatively lower heat generation temperature) are located at the center portion and two outermost sides of the heat generating element 800. Accordingly, in the present embodiment, the two first fin assemblies 20 correspond in position to the two sides of the center portion of the heat generating element 800, and the three second fin assemblies 30 correspond in position to the center portion and the outermost sides of the heat generating element 800. Further, the two first fin assemblies 20 and the three second fin assemblies 30 are arranged successively.

More specifically, in the present embodiment, each of the first fin assemblies 20 includes a plurality of first fins 201, and each of the second fin assemblies 30 includes a plurality of second fins 301. In addition, an arrangement density of the first fins 201 of the first fin assembly 20 is greater than an arrangement density of the second fins 301 of the second fin assembly 30, and a fin height of the first fins 201 of the first fin assembly 20 is greater than a fin height of the second fins 301 of the second fin assembly 30.

In the present embodiment, a fin quantity of each of the first fin assemblies 20 and a fin quantity of each of the second fin assemblies 30 are not specifically limited in the present disclosure. However, the fin quantity of each of the first fin assemblies 20 is preferably greater than the fin quantity of each of the second fin assemblies 30.

In the present embodiment, a porosity of each of the first fin assemblies 20 and a porosity of each of the second fin assemblies 30 are both higher than a porosity of the immersion type heat dissipation base 10. Further in the present embodiment, the porosity of each of the first fin assemblies 20 and the porosity of each of the second fin assemblies 30 are designed to be more than or equal to 50% and less than or equal to 95%. Moreover, in the present embodiment, the porosity of each of the first fin assemblies 20 can also be higher than the porosity of each of the second fin assemblies 30.

It should be noted that a porous structure in the present embodiment is shown in an exaggerated or enlarged manner, so as to facilitate a better understanding of the present disclosure.

In the present embodiment, each of the first fin assemblies 20 and each of the second fin assemblies 30 can be formed on a surface of the immersion type heat dissipation base 10 in an integral manner or by welding. However, preferably, each of the first fin assemblies 20 and each of the second fin assemblies 30 are integrally formed on the surface of the immersion type heat dissipation base 10.

Therefore, in the present embodiment, the two first fin assemblies 20 formed on the surface of the immersion type heat dissipation base 10 are located directly above the two predetermined high-temperature heat source areas 801 of the heat generating element 800. In addition, compared with the second fins 301, the first fins 201 of the two first fin assemblies 20 are arranged more densely, and the fin height of the first fins 201 of the two first fin assemblies 20 is greater. In this way, under the condition that an overall mass change of a product is small, a more ideal utilization rate of a surface area of the immersion type heat dissipation base 10 can be obtained, thereby enhancing an immersion type heat dissipation effect.

### Beneficial Effects of the Embodiments

In conclusion, in the two-phase immersion type heat dissipation substrate provided by the present disclosure, by virtue of “the immersion type heat dissipation base having an upper surface and a lower surface, the lower surface being configured to be in contact with the heat generating element, and the at least one first fin assembly and the at least one second fin assembly being formed on the upper surface”, “the at least one first fin assembly being located directly above at least one high-temperature heat source area of the heat generating element, and the at least one second fin assembly being located directly above an area that is not the at least one high-temperature heat source area of the heat generating element”, “the at least one first fin assembly including a plurality of first fins, and the at least one second fin assembly including a plurality of second fins”, and “an arrangement density of the plurality of first fins being greater than an arrangement density of the plurality of second fins, and a fin height of the plurality of first fins being greater than a fin height of the plurality of second fins,” the immersion type heat dissipation effect can be effectively enhanced.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A two-phase immersion type heat dissipation substrate configured to be in contact with a heat generating element, comprising:
an immersion type heat dissipation base;
at least one first fin assembly; and
at least one second fin assembly;
wherein the immersion type heat dissipation base has an upper surface and a lower surface, the lower surface is configured to be in contact with the heat generating element, and the at least one first fin assembly and the at least one second fin assembly are formed on the upper surface; wherein the at least one first fin assembly is located directly above at least one high-temperature heat source area of the heat generating element, and the at least one second fin assembly is located directly above an area that is not the at least one high-temperature heat source area of the heat generating element; wherein the at least one first fin assembly includes a plurality of first fins, the at least one second fin assembly includes a plurality of second fins, an arrangement density of the plurality of first fins is greater than an arrangement density of the plurality of second fins, and a fin height of the plurality of first fins is greater than a fin height of the plurality of second fins.

2. The two-phase immersion type heat dissipation substrate according to claim 1, wherein the immersion type heat dissipation base is made from one of aluminum, copper, aluminum alloy, and copper alloy.

3. The two-phase immersion type heat dissipation substrate according to claim 2, wherein the immersion type heat dissipation base is immersed in a two-phase coolant, and is configured as a porous metal heat sink having a porosity greater than 5%.

4. The two-phase immersion type heat dissipation substrate according to claim 3, wherein a porosity of the at least one first fin assembly and a porosity of the at least one second fin assembly are both higher than a porosity of the immersion type heat dissipation base.

5. The two-phase immersion type heat dissipation substrate according to claim 1, wherein a fin quantity of the at least one first fin assembly is greater than a fin quantity of the at least one second fin assembly.

6. The two-phase immersion type heat dissipation substrate according to claim 1, wherein the at least one first fin assembly and the at least one second fin assembly are integrally formed on the upper surface of the immersion type heat dissipation base.

7. The two-phase immersion type heat dissipation substrate according to claim 1, wherein the at least one first fin assembly and the at least one second fin assembly are arranged successively.
